(19) United States
(12) Patent Application Publication
(10) Pub. No.: US 2026/0153562 A1
(43) Pub. Date: Jun. 4, 2026

(54) ISOCHRONOUS PHASE-DRIFT TRACKING SYSTEM

(71) Applicant: NORTHROP GRUMMAN SYSTEMS CORPORATION, FALLS CHURCH, VA (US)

(72) Inventor: HAITAO O. DAI, Ellicott City, MD (US)

(21) Appl. No.: 18/965,525

(22) Filed: Dec. 2, 2024

(51) Int. Cl. G01R 31/317; G01R 27/28; H03K 5/00; H03K 5/01; H03K 19/21

(52) U.S. Cl. CPC G01R 31/31727; G01R 27/28; G01R 31/31725; H03K 5/01; H03K 19/21; H03K 2005/00013; H03K 2005/00286

(57) ABSTRACT

One example includes an isochronous phase-drift tracking receiver system. The system is configured to receive a sequence of pulses from a transmitter system that operates from a first clock signal via a transmission line. The system is also configured to initially align the sequence of pulses to a defined phase of a second clock signal. The system is further configured to generate a phase-tracking signal having a first state that is indicative of a phase of the sequence of pulses being aligned to the defined phase of the second clock signal and a second state that is indicative of the phase of the sequence of pulses being misaligned to the defined phase of the second clock signal.

### GOVERNMENT INTEREST

The invention was made under Government Contract. Therefore, the US Government has rights to the invention as specified in an associated contract.

### TECHNICAL FIELD

This disclosure relates generally to superconducting computer systems, and more specifically to an isochronous phase-drift tracking system.

### BACKGROUND

Computer systems typically implement communication between separate chips, separate printed circuit boards, and/or separate computer systems. To properly implement inter-chip or other types of communication (e.g., across a bus), a clock signal can be used to properly time the transmitter and the receiver to appropriately sample the data being transmitted, such that the receiver can properly receive and process the data. However, because the clock signal can be generated from multiple sources, or can be transmitted across the inter-chip communication system, the clock signals that are implemented for transmission and for reception of the data can have an unknown or arbitrary phase relation, which can be referred to as isochronous communication. Certain types of communication, such as certain types of superconducting logic (e.g., reciprocal quantum logic, or RQL) implement the clock signal as a power source, thus precluding the possibility of clock recovery with the associated AC clock signal.

### SUMMARY

One example includes an isochronous phase-drift tracking receiver system. The system is configured to receive a sequence of pulses from a transmitter system that operates from a first clock signal via a transmission line. The system is also configured to initially align the sequence of pulses to a defined phase of a second clock signal. The system is further configured to generate a phase-tracking signal having a first state that is indicative of a phase of the sequence of pulses being aligned to the defined phase of the second clock signal and a second state that is indicative of the phase of the sequence of pulses being misaligned to the defined phase of the second clock signal.

Another example includes a method for tracking phase-drift of data from a transmission line. The method includes receiving a sequence of pulses at a phase-drift receiver from a transmitter system that operates from a first clock signal via the transmission line and splitting each of the pulses into a plurality of single flux quantum (SFQ) pulses. The method also includes providing a second clock signal to an SFQ to reciprocal quantum logic (RQL) converter system of the phase-drift receiver to convert the SFQ pulses into at least one RQL signal. Each of the at least one RQL signal can be associated with a respective one of a plurality of phases of the second clock signal. One of the at least one RQL signal can correspond to a phase-alignment signal that is aligned to a defined phase of the second clock signal. The method further includes generating a phase-tracking signal having a first state that is indicative of a phase of the phase-alignment signal being aligned to the defined phase of the second clock signal and a second state that is indicative of the phase of the respective one of the phase-alignment signal being misaligned to the defined phase of the second clock signal.

Another example includes an isochronous phase-drift tracking system. The system includes a transmitter system comprising a phase-drift tracking transmitter configured to generate a sequence of pulses. The system also includes a transmission line to transmit the sequence of pulses from the transmitter system. The system further includes a receiver system comprising an isochronous phase-drift tracking receiver system configured to receive a sequence of pulses from a transmitter system that operates from a first clock signal via a transmission line. The receiver system is also configured to initially align the sequence of pulses to a defined phase of a second clock signal. The receiver system is further configured to generate a phase-tracking signal having a first state that is indicative of a phase of the sequence of pulses being aligned to the defined phase of the second clock signal and a second state that is indicative of the phase of the sequence of pulses being misaligned to the defined phase of the second clock signal.

### BRIEF DESCRIPTION OF THE DRAWINGS

FIG. 1 illustrates an example block diagram of an isochronous phase-drift tracking system.

FIG. 2 illustrates an example block diagram of an isochronous phase-drift tracking receiver system.

FIG. 3 illustrates another example block diagram of a phase-drift receiver.

FIG. 4 illustrates an example circuit diagram of an SFQ receiver.

FIG. 5 illustrates an example circuit diagram of an SFQ splitter.

FIG. 6 illustrates an example circuit diagram of an SFQ-to-RQL converter.

FIG. 7 illustrates another example block diagram of a phase-drift receiver.

FIG. 8 illustrates an example block diagram of digital logic.

FIG. 9 illustrates an example circuit diagram of digital logic.

FIG. 10 illustrates another example circuit diagram of digital logic.

FIG. 11 illustrates an example of a method for tracking phase-drift in an isochronous phase-drift tracking system.

### DETAILED DESCRIPTION

This disclosure relates generally to superconducting computer systems, and more specifically to an isochronous phase-drift tracking system. The isochronous phase-drift tracking system can be implemented in a variety of superconducting inter-chip communication systems, such as in a reciprocal quantum logic (RQL) computer system, to track clock phase-drift between different circuits (e.g., different IC chips and/or between circuits in different temperature environments). The isochronous phase-drift tracking system includes a transmitter system that includes a phase-drift tracking transmitter and a receiver system that includes an isochronous phase-drift tracking receiver system. The phase-drift tracking transmitter and the isochronous phase-drift tracking receiver system can be communicatively coupled via a transmission line (e.g., a passive transmission line (PTL)). The phase-drift tracking transmitter includes a pulse generator configured to generate a sequence of pulses (e.g., reciprocal quantum logic (RQL) pulses) operating from a first clock signal (e.g., an AC clock signal, such as an RQL clock signal) and a low bandwidth driver that is configured to transmit the sequence of pulses across the transmission line. The isochronous phase-drift tracking receiver system is configured to receive the sequence of pulses from the transmission line and to initially align the pulses to a defined phase of a second clock signal. The isochronous phase-drift tracking receiver system can also generate a phase-tracking signal that has a first state that indicates the alignment of the pulses to the defined phase, and a second state that indicates the misalignment of the pulses to the defined phase. Therefore, the isochronous phase-drift tracking receiver system can indicate phase drift of the transmission of data between the transmitter system and the receiver system.

As an example, the isochronous phase-drift tracking receiver system can include an SFQ splitter stage that is configured to split each of the pulses into a plurality of SFQ pulses. The SFQ pulses can be provided to a respective plurality of SFQ to RQL converters that are provided the second clock signal to convert the SFQ pulses into at least one RQL signal, with each of the RQL signal(s) being associated with a separate respective phase of the second clock signal (e.g., associated with sequential 90° phases of the second clock signal). Thus, based on the respective timing of the SFQ pulses, the associated RQL signal(s) can be approximately aligned on or between the phases of the second clock signal based on timing windows between respective RQL phases. For example, a given SFQ pulse can be provided between or can drift between one phase and an adjacent phase (ahead or behind) of the second clock signal. The RQL signal(s) can thus be provided to digital logic that is configured to generate a phase-alignment signal corresponding to a sequence of RQL pulses that are aligned with the defined phase of the second clock signal. Therefore, the phase-alignment signal is indicative that the phase of the SFQ pulses are aligned to the second clock signal, such that a change in state of the phase-alignment signal is indicative of a phase-drift of the SFQ pulses from the second clock signal.

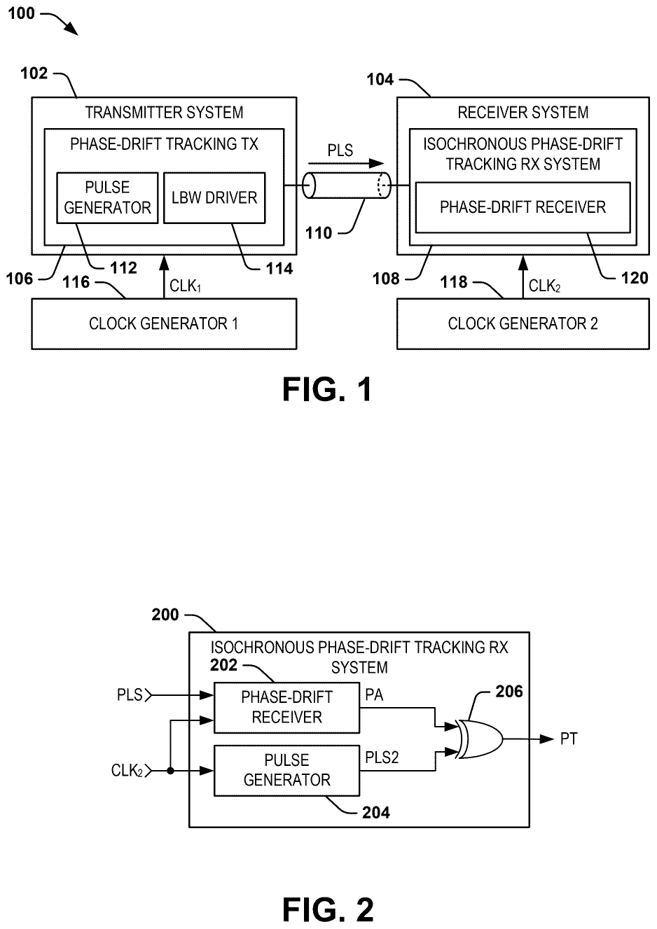

FIG. 1 illustrates an example of an isochronous phase-drift tracking system 100. The isochronous phase-drift tracking system 100 can be implemented in any of a variety of computer systems that implement inter-chip communications in superconducting data transfer system (e.g., in a reciprocal quantum logic (RQL) communication system). The isochronous phase-drift tracking system 100 can be implemented to track phase-shift between different clock signals that are located on or are provided to different circuit systems. Therefore, the isochronous phase-drift tracking system can allow inter-chip communication in a manner that can maintain a phase relationship between data provided between different circuit systems that communicate data across transmission lines.

The isochronous phase-drift tracking system 100 includes a transmitter system 102 and a receiver system 104. The transmitter system 102 includes a phase-drift tracking transmitter 106 and the receiver system 104 includes an isochronous phase-drift tracking receiver system 108. The phase-drift tracking transmitter 106 and the isochronous phase-drift tracking receiver system 108 are separated by a transmission line 110. The phase-drift tracking transmitter 106 includes a pulse generator 112 and a low bandwidth (LBW) driver 114. The pulse generator 112 is configured to generate a sequence of pulses (e.g., single flux quantum (SFQ) pulses or RQL pulses) based on a first clock signal CLK₁ that is generated by a first clock generator 116. The first clock signal CLK₁ can be implemented to provide timing operations for the entirety of the transmitter system 102 and the associated circuit in which the transmitter system 102 is included. The pulses are transmitted across the transmission line 110 via the LBW driver 114, with the pulses being demonstrated in the example of FIG. 1 as a signal PLS.

The isochronous phase-drift tracking receiver system 108 is configured to receive the pulses and to align the pulses to a specific defined phase of a second clock signal CLK₂ that is generated by a second clock generator 118. The second clock signal CLK₂ can be implemented to provide timing operations for the entirety of the receiver system 104 and the associated circuit in which the receiver system 104 is included. The isochronous phase-drift tracking receiver system 108 can be configured, for example, to generate a phase-tracking signal (e.g., internal to the receiver system 104) that can be indicative of the alignment of the pulses to the specific defined phase of the second clock signal CLK₂, and thus the approximate alignment of the phases of the first and second clock signals CLK₁ and CLK₂.

However, over a period of time and/or based on a variety of environmental considerations, the relative phase between the first and second clock signals CLK₁ and CLIK2 can drift. Therefore, in response to a logic-state change of the phase-tracking signal, the receiver system 104 can identify phase-drift between the first and second clock signals CLK₁ and CLK₂. Accordingly, in response to identifying the phase drift between the first and second clock signals CLK₁ and CL2, the transmitter system 102 and/or the receiver system 104 can be configured to provide any of a variety of clock realignment techniques to realign the phases between the first clock signal CLK₁ and the second clock signal CLK₂.

As an example, the isochronous phase-drift tracking receiver system 108 can include a phase-drift receiver 120 that is configured to convert the pulses to a phase-alignment signal that can correspond to a sequence of RQL pulses that are provided at each of the specific defined phase intervals of the second clock signal CLK₂. For example, the phase-drift receiver 120 can convert the pulses into SFQ pulses, and can convert and align each of the SFQ pulses in at least one RQL signal, each of which being aligned to one or more of the phase intervals of the second clock signal CLK₂. As an example, the phase-drift receiver 120 can convert the SFQ pulses to the RQL signal(s) in a manner that includes a significant phase overlap between the sampling phases to allow the SFQ pulses to be sampled regardless of the phase of arrival along the period of the second clock signal CLK₂. For example, the second clock signal CLK₂ can correspond to an RQL clock signal that includes an in-phase component and a quadrature-phase component, and can thus include sampling increments of approximately 90°.

As described herein, the phase-drift receiver 120 can include a digital logic that can convert the RQL signal(s) to a single RQL signal that is aligned to and provided at the specific defined phase of each period of the second clock signal CLK₂. Therefore, the sequence of RQL signals provided at each period of the second clock signal CLK₂ can correspond to a phase-alignment signal. As an example, the phase-alignment signal can correspond to the phase-tracking signal, such as to indicate the phase alignment of the received pulses to the specific defined phase of the second clock signal CLK₂. As another example, the phase-alignment signal can be provided in further logic operations to provide the phase-tracking signal.

The digital logic can be configured to provide the indication of phase alignment at a given resolution that can be based on physical characteristics of the transmission lines between the transmitter system 102 and the receiver system 104 across which data is provided. As a first example, the transmission lines between the transmitter system 102 and the receiver system 104 can be approximately equal in length. Thus, in the first example, the digital logic can be fabricated to have a relatively coarse resolution, and thus a large phase overlap between the sampling phases of the second clock signal CLK₂ with respect to the indication of phase misalignment. As a result, the relative phase between the first and second clock signals CLK₁ and CLK₂ can exhibit a relatively larger phase drift before the phase-drift receiver 120 changes the state of the phase-alignment signal to indicate phase misalignment between the first and second clock signals CLK₁ and CLK₂.

As a second example, the transmission lines between the transmitter system 102 and the receiver system 104 can vary in length. Thus, in the second example, the digital logic can be fabricated to have a relatively fine resolution, and thus a smaller phase overlap between the sampling phases of the second clock signal CLK₂ with respect to the indication of phase misalignment. As a result, the relative phase between the first and second clock signals CLK₁ and CLK₂ can exhibit a relatively smaller phase drift before the phase-drift receiver 120 changes the state of the phase-alignment signal to indicate phase misalignment between the first and second clock signals CLK₁ and CLK₂.

Based on changes to the state of the phase-tracking signal, and thus the indication of phase-alignment, the transmitter system 102 and/or the receiver system 104 can make periodic adjustments to phase alignment. Accordingly, the transmitter system 102 and the receiver system 104 can maintain data transfer integrity across transmission lines despite experiencing periodic phase-drift.

FIG. 2 illustrates an example block diagram of an isochronous phase-drift tracking receiver system 200. The isochronous phase-drift tracking receiver system 200 can correspond to the isochronous phase-drift tracking receiver system 108 in the example of FIG. 1. Thus, the isochronous phase-drift tracking receiver system 200 is demonstrated as receiving the sequence of pulses PLS at an input, as well as the second clock signal CLK₂.

In the example of FIG. 2, isochronous phase-drift tracking receiver system 200 includes a phase-drift receiver 202 and a pulse generator 204. The phase-drift receiver 202 is configured to receive the pulses PLS and the second clock signal CLK₂ to initially align the pulses PLS to a specific defined phase of the second clock signal CLK₂. Therefore, the phase-drift receiver 202 is configured to generate a phase-alignment signal PA that can correspond to a sequence of RQL pulses at the specific defined phase in each period of the second clock signal CLK₂. The pulse generator 204 can likewise generate a sequence of RQL pulses, demonstrated as PLS2, at the specific defined phase in each period of the second clock signal CLK₂. As an example, the pulse generator 204 can initially generate a training sequence that includes a combination of logic-0 (e.g., no clock-aligned pulse) and one or more isolated logic-1 pulses (e.g., clock-aligned RQL pulses between sets of no clock-aligned pulse(s)) to provide an initial training phase of operation for the isochronous phase-drift tracking receiver system 200. Therefore, the phase-alignment signal PA is initially phase-aligned to the sequence of RQL pulses PLS2 that are provided from the pulse generator 204.

The phase-alignment signal PA and the RQL pulses PLS2 are provided to an XOR-gate 206 (e.g., an RQL XOR-gate) to provide a logic XOR-operation on the phase-alignment signal PA and the RQL pulses PLS2 at the defined phase of each period of the clock signal CLK₂. The output of the XOR-gate 206, and thus the logic XOR-operation on the phase-alignment signal PA and the RQL pulses PLS2, is demonstrated as the phase-tracking signal PT. Therefore, during normal operation of the receiver system 104, the XOR-gate 206 provides the phase-tracking signal PT as a logic-0 (e.g., no pulses) at the defined phase of the second clock signal CLK₂. However, in response to a phase-drift of the pulses PLS relative to the second clock signal CLK₂, such as greater than a threshold angle, the XOR-gate 206 provides the phase-tracking signal PT as a logic-1 (e.g., a sequence of RQL pulses) at the defined phase of each period of the second clock signal CLK₂. As described herein, the threshold angle can be defined by the fabrication design characteristics of the phase-drift receiver 202.

Accordingly, the isochronous phase-drift tracking receiver system 200 in the example of FIG. 2 is one example of an isochronous phase-drift tracking receiver system as described herein. As another example, the pulse generator 204 and the XOR-gate 206 can be omitted, such that the phase-alignment signal PA corresponds to the phase-tracking signal PT. In such example, during normal operation of the receiver system 104, the phase-drift receiver 202 provides the phase-alignment signal PA as a logic-1 (e.g., a sequence of RQL pulses) at the defined phase of the second clock signal CLK₂. However, in response to a phase-drift of the pulses PLS relative to the second clock signal CLK₂, such as greater than the threshold angle, the phase-drift receiver 202 provides the phase-alignment signal PA as a logic-0 (e.g., no pulse) at the defined phase of each period of the second clock signal CLK₂.

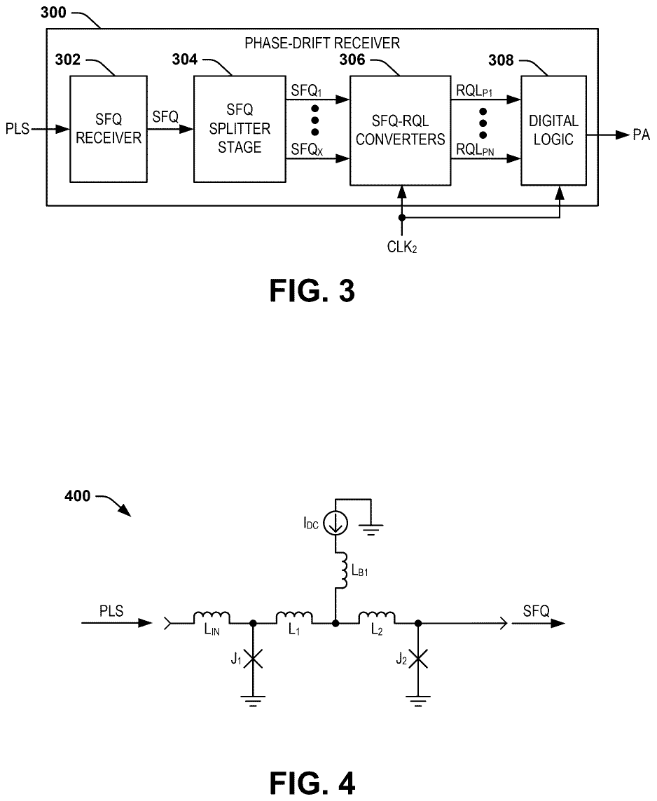

FIG. 3 illustrates an example of a phase-drift receiver 300. The phase-drift receiver 300 can correspond to the phase-drift receiver 120 or the phase-drift receiver 202 in the respective examples of FIGS. 1 and 2, and can thus be configured to generate the phase-alignment signal PA that is indicative of the phase-alignment of the pulses PLS to the defined phase of the second clock signal CLK₂.

The phase-drift receiver 300 includes an SFQ receiver 302 and one or more SFQ splitters 304. The SFQ receiver 302 can be configured to convert the received pulses PLS into SFQ pulses, such as via a DC current bias and one or more Josephson junctions. The SFQ receiver 302 can be configured to provide a single SFQ pulse “SFQ”. The SFQ pulses SFQ is provided to one or more SFQ splitter in an SFQ splitter stage 304. As an example, the SFQ splitter(s) can each be configured to generate a pair of SFQ pulses from an input SFQ pulse. For example, the SFQ splitter stage 304 can include cascaded SFQ splitters, such that the SFQ splitters of the SFQ splitter stage 304 can each generate pairs of the SFQ pulses in a cascaded sequence.

In the example of FIG. 3, the SFQ splitter stage 304 is demonstrated as generating a plurality of SFQ pulses SFQ₁ through SFQ_{X}, where X corresponds to an index of a quantity of SFQ pulses that is split by the SFQ splitter(s) 304 from a single input SFQ pulse. As an example, the SFQ splitter stage 304 can include one or more 1:2 arrangements of three SFQ splitters that are collectively configured to split an SFQ pulse into a total of four SFQ pulses (e.g., X=4).

The quantity of SFQ pulses SFQ₁ through SFQ_{X} can correspond to a quantity of sampling times in a given period of the second clock signal CLK₂. The SFQ pulses SFQ₁ through SFQ_{X} are thus input to a respective plurality of SFQ-RQL converters 306 configured to convert the SFQ pulses into RQL signals. The SFQ-RQL converters 306 can each operate from a different sampling phase of the second clock signal CLK₂, such that the SFQ pulses get sampled (e.g., based on a time of bias of one or more Josephson junctions) at one or more of the sampling phases based on a time of arrival of the SFQ pulses SFQ₁ through SFQ_{X}. In the example of FIG. 3, the RQL signals are demonstrated as RQL_{P1} through RQL_{PN}, with 1 through N corresponding to different phases of the second clock signal CLK₂.

FIG. 4 illustrates an example circuit diagram of an SFQ receiver 400. The SFQ receiver 400 can correspond to the SFQ receiver 302 in the example of FIG. 3. The SFQ receiver 400 is demonstrated as receiving a pulse PLS from the transmission line 110. The pulse PLS is provided through an input inductor L_{1N} to a Josephson transmission line (JTL) segment. The JTL segment is formed from a pair of inductors L₁ and L₂, a pair of Josephson junctions J₁ and J₂, and a DC bias current I_{DC} provided through a bias inductor L_{B1}. Therefore, in response to the pulse PLS, the Josephson junctions J₁ and J₂, biased by the DC bias current I_{DC}, trigger to generate an SFQ pulse SFQ at an output of the SFQ receiver 400.

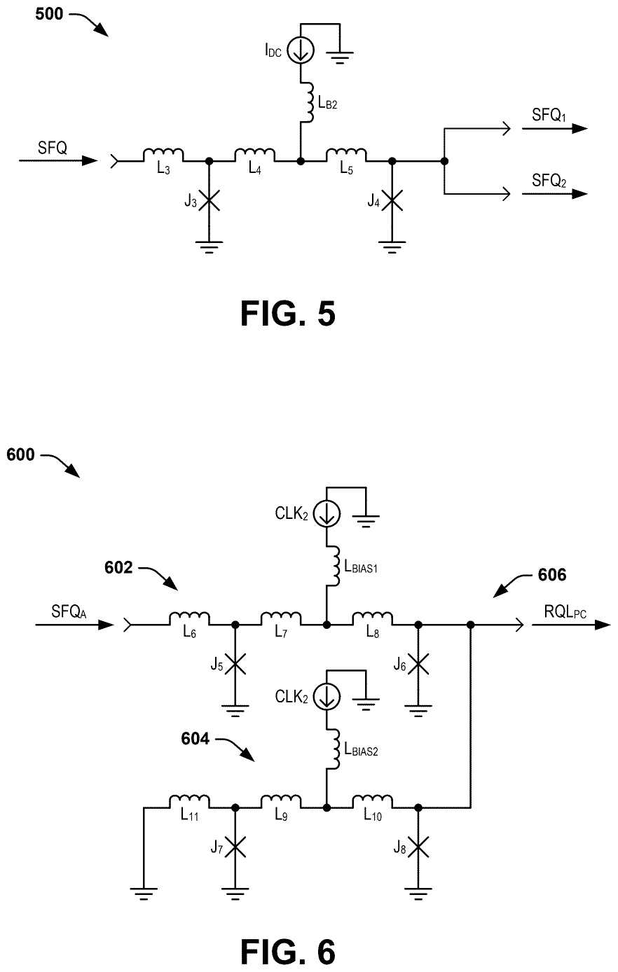

FIG. 5 illustrates an example circuit diagram of an SFQ splitter 500. The SFQ splitter 500 can correspond to one of the SFQ splitter(s) 304 in the example of FIG. 3. The SFQ splitter 500 is demonstrated as receiving an SFQ pulse SFQ. The SFQ pulse SFQ is provided through an input inductor L₃ to a JTL segment formed from a pair of inductors L₄ and L₅, a pair of Josephson junctions J₃ and J₄, and a DC bias current I_{DC} (e.g., having a same amplitude as the DC bias current I_{DC} as demonstrated in the example of FIG. 3) provided through a bias inductor L_{B2}. Therefore, in response to the SFQ pulse SFQ, the Josephson junctions J₃ and J₄, biased by the DC bias current I_{DC}, trigger to generate an SFQ pulse. In the example of FIG. 5, the SFQ pulse is split to provide the SFQ pulses SFQ₁ and SFQ₂. The SFQ pulses SFQ₁ and SFQ₂ are then provided to separate respective SFQ splitters (e.g., fabricated the same as the SFQ splitter 500) or to separate respective SFQ-RQL converters 306 that are associated with separate respective phases of the second clock signal CLK₂.

FIG. 6 illustrates an example of an SFQ-RQL converter 600. The SFQ-RQL converter 600 can correspond to any one of the SFQ-RQL converters 306 in the example of FIG. 3, and can thus be configured to generate an RQL signal that either has a fluxon/anti-fluxon pair or not depending on a relative timing between the arrival of the input SFQ pulse SFQ_{A}, where A is an index corresponding to one of the SFQ pulses SFQ₁ through SFQ_{X}, and the respective sampling phase of the second clock signal CLK₂.

The SFQ-RQL converter 600 includes a first input JTL stage 602 and a second input JTL stage 604. The first input JTL stage 602 is configured to receive the input SFQ pulse SFQ_{A} and propagate the input SFQ pulse SFQ_{A} to an output 606 as an output RQL signal RQLPC, where C is an index of one of the RQL signals RQL_{P1} through RQL_{PN}. The first input JTL stage 602 includes an input inductor L₆ through which the SFQ pulse SFQ_{A} propagates and a first Josephson junction J₅ that is triggered in response to the SFQ pulse SFQ_{A} based on the second clock signal CLK₂ (e.g., provided as an AC bias signal). The second clock signal CLK₂ is provided through a first bias inductor L_{BIAS1} to bias the first Josephson junction J₅ and a second Josephson junction J₆ via respective inductors L₇ and L₈, such that the SFQ pulse SFQ_{A} propagates through the inductors L₇ and L₈ in response to the first Josephson junction J₅ triggering, to subsequently trigger the Josephson junction J₆ to provide the SFQ pulse SFQ_{A} to the output 606 as the fluxon of the RQL signal RQLPC.

The second input JTL stage 604 is configured substantially similarly with respect to the first input JTL stage 602. Particularly, the second input JTL stage 604 includes a pair of Josephson junctions J₇ and J₈ that are arranged opposite each other with respect to the second clock signal CLK₂ through a second bias inductor L_{BIAS2} and through inductors L₉ and L₁₀. However, the second input JTL stage 604 also includes an inductor Lu that is coupled to ground, such that the second input JTL stage 604 generates an anti-fluxon in response to the fluxon corresponding to the SFQ pulse SFQ_{A}. Therefore, in response to the SFQ pulse SFQ_{A} being provided at the first input JTL stage 602, the second input JTL stage 604 generates a corresponding anti-fluxon of the RQL signal RQL_{PN} at the output 606.

Referring back to the example of FIG. 3, the RQL signal(s) RQL_{P1} through RQL_{PN} are provided to digital logic 308 that is configured to align one of the RQL signals RQL_{P1} through RQL_{PN} to the defined phase of the second clock signal CLK₂ to generate the phase-alignment signal PA. As an example, the digital logic 308 is configured to phase-align and delay each of the plurality of RQL signal(s) RQL_{P1} through RQL_{PN} into sets of phase-aligned and delayed RQL signals. The digital logic 308 can also be configured to latch the at least one RQL signal associated with the phase-aligned and delayed RQL signal(s) associated with the phase-aligned and delayed RQL signal(s) RQL_{P1} through RQL_{PN} in response to at least one trigger signal, and can align one of the RQL signal(s) RQL_{P1} through RQL_{PN} to the sampling phase of the second clock signal CLK₂ corresponding to the defined phase to provide the phase-alignment signal PA.

As described herein, the term “signal” refers to either the presence of or absence of a pulse (e.g., SFQ signal, RQL signal, phase-alignment signal, and/or phase-tracking signal). In some examples herein, such as the RQL signals generated by the SFQ-RQL converters 306 that sample the SFQ pulse at a specific phase to generate an RQL pulse, the term “signal” can also refer specifically to the presence of a pulse (e.g., the RQL signal(s) RQL₀, RQL₉₀, RQL₁₈₀, and RQL₂₇₀).

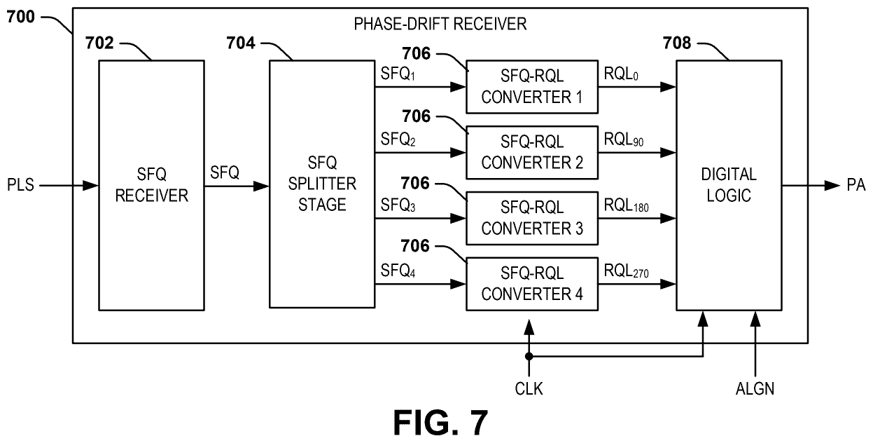

FIG. 7 illustrates an example of a phase-drift receiver 700. The phase-drift receiver 700 can correspond to the phase-drift receiver 120, the phase-drift receiver 202, or the phase-drift receiver 300 in the respective examples of FIGS. 1-3, and can thus be configured to generate the phase-alignment signal PA that is indicative of the phase-alignment of the pulses PLS to the defined phase of the second clock signal CLK₂. The example of FIG. 7 is demonstrated as implementing the second clock signal CLK₂ as an RQL clock signal having four sampling phases (e.g., 0°, 90°, 180°, and 270°).

The phase-drift receiver 700 includes an SFQ receiver 702 (e.g., the SFQ receiver 400) and an SFQ splitter stage 704 (e.g., a cascaded set of the SFQ splitters 500). The SFQ receiver 702 is configured to convert the received pulses PLS into an SFQ pulse SFQ, and the SFQ splitters of the SFQ splitter stage 704 are each configured to generate a pair of SFQ pulses from a respective input SFQ pulse. In the example of FIG. 7, the SFQ splitters of the SFQ splitter stage 704 can generate four SFQ pulses SFQ₁, SFQ₂, SFQ₃, and SFQ₄ from the SFQ pulse SFQ.

Each of the SFQ pulses SFQ₁, SFQ₂, SFQ₃, and SFQ₄ is provided to a separate respective SFQ-RQL converter 706. Each of the SFQ-RQL converters 706 can be provided with a respective inductive coupling to the second clock signal CLK₂ that corresponds to a specific respective one of the phases. For example, the first of the SFQ-RQL converters 706 can be associated with the 0° phase of the period of the second clock signal CLK₂, and the second of the SFQ-RQL converters 706 can be associated with the 90° phase of the period of the second clock signal CLK₂. Similarly, the third of the SFQ-RQL converters 706 can be associated with the 180° phase of the period of the second clock signal CLK₂, and the fourth of the SFQ-RQL converters 706 can be associated with the 270° phase of the period of the second clock signal CLK₂. Therefore, each of the SFQ-RQL converters 706 is configured to generate an RQL signal, demonstrated in the example of FIG. 7 as RQL₀, RQL₉₀, RQL₁₈₀, and RQL₂₇₀, respectively.

Each of the RQL signal(s) RQL₀, RQL₉₀, RQL₁₈₀, and RQL₂₇₀ can either include an associated fluxon (e.g., and subsequent anti-fluxon) or not, depending on the timing of the arrival of the respective SFQ pulses SFQ₁, SFQ₂, SFQ₃, and SFQ₄ relative to the sampling time phases of the second clock signal CLK₂. For example, if the SFQ pulses SFQ₁, SFQ₂, SFQ₃, and SFQ₄ have associated SFQ pulses at approximately 120° with respect to a given period of the second clock signal RQL, the RQL signal(s) RQL₉₀ and RQL₁₈₀ can each include a fluxon/anti-fluxon pair. Accordingly, at least one of the RQL signal(s) RQL₀, RQL₉₀, RQL₁₈₀, and RQL₂₇₀ can include a fluxon/anti-fluxon pair corresponding to one of the SFQ pulses SFQ₁, SFQ₂, SFQ₃, and SFQ₄.

As an example, the second clock signal CLK₂ can be a sinusoidal AC signal having a positive amplitude for approximately 180°. For example, depending on various fabrication factors and design requirements, the phase-drift receiver 700 can accept an input pulse of one of the SFQ pulses SFQ₁, SFQ₂, SFQ₃, and SFQ₄ for a subset of the 180°, typically about 120°. The amount of overlap between two of the SFQ-RQL converters 706 that are spaced apart by 90° degrees can depend on a number of factors, including how close the second clock signal CLK₂ comes to the actual desired spacing in degrees, thermal noise, and how wide the receiver window is. Therefore, the SFQ-RQL converters 706 can be designed to have some amount of overlap, as described previously with respect to the timing of the arrival of the respective SFQ pulses SFQ₁, SFQ₂, SFQ₃, and SFQ₄ relative to the sampling time phases of the second clock signal CLK₂. The RQL signal(s) RQL₀, RQL₉₀, RQL₁₈₀, and RQL₂₇₀ are thus provided to a digital logic 708.

The amount of overlap, and thus the amount of resolution of the angular phase-drift of the phase-drift receiver 700, can be based on the composition of the digital logic 708. For example, the digital logic can be configured to phase-align and delay one or more of the RQL signal(s) RQL₀, RQL₉₀, RQL₁₈₀, and RQL₂₇₀, and to perform logic operations on multiple sets of the phase-aligned and delayed RQL signal(s) RQL₀, RQL₉₀, RQL₁₈₀, and RQL₂₇₀ to provide the phase-alignment signal at a given resolution. The resolution can be based on the logic operations provided by the digital logic 708.

As a first example, the transmission lines between the transmitter system 102 and the receiver system 104 can be approximately equal in length. Thus, in the first example, the digital logic 708 can be fabricated to have a relatively low resolution corresponding to the phase-drift threshold, such as up to a complete timing window of the respective SFQ-RQL converters 706 (e.g., 120° of the second clock signal CLK₂). Thus, the digital logic 708 in the first example has a large phase-drift threshold of the second clock signal CLK₂ with respect to the indication of phase misalignment. As a result, the relative phase between the first and second clock signals CLK₁ and CLK₂ can exhibit a relatively larger phase drift before the phase-drift receiver 700 changes the state of the phase-alignment signal to indicate phase misalignment between the first and second clock signals CLK₁ and CLK₂

As a second example, the transmission lines between the transmitter system 102 and the receiver system 104 can vary in length. Thus, in the second example, the digital logic 708 can be fabricated to have a relatively high resolution corresponding to the phase-drift threshold, such as a much smaller timing window with respect to the respective SFQ-RQL converters 706 (e.g., 45° of the second clock signal CLK₂). Thus, the digital logic 708 in the second example has a small phase-drift threshold of the second clock signal CLK₂ with respect to the indication of phase misalignment. As a result, the relative phase between the first and second clock signals CLK₁ and CLK₂ can exhibit a relatively smaller phase drift before the phase-drift receiver 700 changes the state of the phase-alignment signal to indicate phase misalignment between the first and second clock signals CLK₁ and CLK₂.

While the example of FIG. 7 demonstrates four separate sampling phases of the second clock signal CLK₂, the phase-drift receiver 700 can include a different quantity of sampling phases of the second clock signal CLK₂. For example, the phase-drift receiver 700 can instead include eight sampling phases, such as at every 45° increment, for a higher resolution of phase-drift sensing.

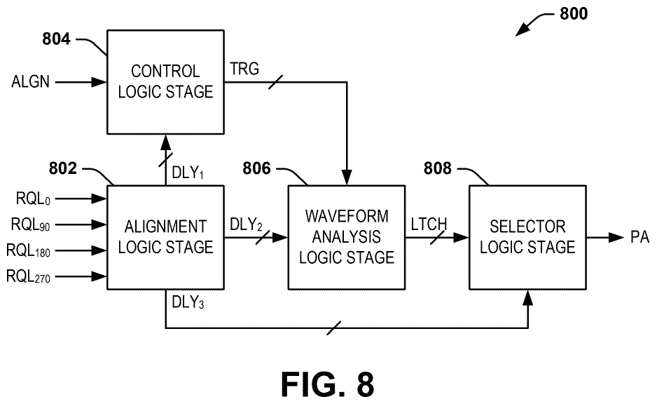

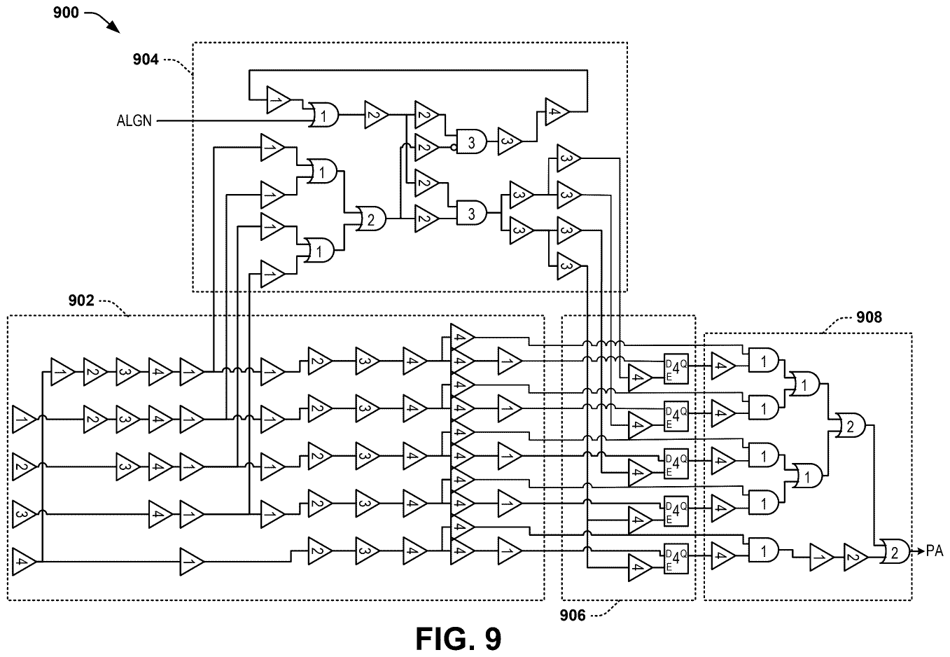

FIG. 8 illustrates an example diagram of digital logic 800. The digital logic 800 can demonstrate a more detailed version of the digital logic 708 in the example of FIG. 7. Particularly, the digital logic 800 includes multiple stages, and a sequence of the digital logic operations that are conducted on the RQL signal(s) RQL₀, RQL₉₀, RQL₁₈₀, and RQL₂₇₀ to generate the phase-alignment signal. As an example, the stages of the digital logic 708 described herein can be clocked by the second clock signal CLK₂, and can be based on sequences of JTLs that operate at separate respective phases of the second clock signal CLK₂. Additionally, the digital logic 708, as described herein, including the digital logic operations, can be implemented based on RQL digital logic gates that can likewise be clocked by the second clock signal CLK₂.

The digital logic 800 includes an alignment logic stage 802 that is configured to receive the RQL signal(s) RQL₀, RQL₉₀, RQL₁₈₀, and RQL₂₇₀ and to provide phase alignment of the RQL signal(s) RQL₀, RQL₉₀, RQL₁₈₀, and RQL₂₇₀. Therefore, each of the RQL signal(s) RQL₀, RQL₉₀, RQL₁₈₀, and RQL₂₇₀ can be concurrently clocked by a common phase of the second clock signal CLK₂. Therefore, each of the RQL signal(s) RQL₀, RQL₉₀, RQL₁₈₀, and RQL₂₇₀ are aligned to the same phase at a given time. For example, the four phase-consecutive RQL samples provided by the RQL signal(s) RQL₀, RQL₉₀, RQL₁₈₀, and RQL₂₇₀ are presented on phases associated with 0°, 90°, 180°, and 270° degree phases of a period of the second clock signal CLK₂, where 0° represents the sample taken earliest in time, 90° is the sample taken 90° degrees later, up to 270° corresponding to the last sample taken in the period of the second clock signal CLK₂. As an example, the phase-alignment and delay of the RQL signal(s) RQL₀, RQL₉₀, RQL₁₈₀, and RQL₂₇₀ can be performed by each of a plurality of delay paths that each includes a sequence of clocked JTL delay elements. Thus, the JTL delay elements of the alignment logic stage 802 can be added to each of the RQL signal(s) RQL₀, RQL₉₀, RQL₁₈₀, and RQL₂₇₀ to align all of the RQL signal(s) RQL₀, RQL₉₀, RQL₁₈₀, and RQL₂₇₀ to the 270° phase, as an example. Therefore, each of the RQL signal(s) RQL₀, RQL₉₀, RQL₁₈₀, and RQL₂₇₀ are aligned on the same phase of the second clock signal CLK₂ at a given time, even though each of the RQL signal(s) RQL₀, RQL₉₀, RQL₁₈₀, and RQL₂₇₀ are associated with a different sampling time of the respective SFQ pulses SFQ₁, SFQ₂, SFQ₃, and SFQ₄.

Additionally, for example, the alignment logic stage 802 can include a plurality of delay paths that is greater than the number of RQL signal(s), and thus greater than four in the example of FIGS. 7 and 8. Therefore, the alignment logic stage 802 can be configured to generate one or more additional sets (e.g., copies) of the RQL signal(s) RQL₀, RQL₉₀, RQL₁₈₀, and RQL₂₇₀ that are likewise phase-aligned with the RQL signal(s) RQL₀, RQL₉₀, RQL₁₈₀, and RQL₂₇₀. As an example, a set of at least one of the RQL signal(s) RQL₀, RQL₉₀, RQL₁₈₀, and RQL₂₇₀ can be generated by starting with the RQL signal RQL₂₇₀ and adding a full period of the second clock signal CLK₂ of delay to the RQL signal RQL₂₇₀ (e.g., based on four additional JTLs).

Thus, by splitting each of at least one of the plurality of RQL signal(s) RQL₀, RQL₉₀, RQL₁₈₀, and RQL₂₇₀ into more than one of the plurality of delay paths, the digital logic 708 can provide phase-alignment of the phase-alignment signal based on misalignment of the timing of the SFQ pulses SFQ₁, SFQ₂, SFQ₃, and SFQ₄ with respect to a single one of the RQL signal(s) RQL₀, RQL₉₀, RQL₁₈₀, and RQL₂₇₀. Therefore, the digital logic 708 can provide alignment when a single bit is associated with multiple consecutive ones of the RQL signal(s) RQL₀, RQL₉₀, RQL₁₈₀, and RQL₂₇₀, or drift of the timing of a given one of the RQL signal(s) RQL₀, RQL₉₀, RQL₁₈₀, and RQL₂₇₀ to one of a next or previous one of the plurality of delay paths that are sequential in phase relationship with respect to the second clock signal CLK₂ (e.g., drifting from the 90° phase to the 180°, etc.).

In addition, the alignment logic stage 802 can be configured to implement phase delays of the aligned RQL signal(s) RQL₀, RQL₉₀, RQL₁₈₀, and RQL₂₇₀, and can provide separate sets of the delayed RQL signal(s) RQL₀, RQL₉₀, RQL₁₈₀, and RQL₂₇₀ to different portions of the digital logic 708. In the example of FIG. 5, the delayed sets of the RQL signal(s) RQL₀, RQL₉₀, RQL₁₈₀, and RQL₂₇₀ are demonstrated as DLY₁, DLY₂, and DLY₃.

The digital logic 800 also includes a control logic stage 804 that is configured to receive a first delayed set of the RQL signal(s) DLY₁. The control logic stage 804 is configured to also receive the alignment signal ALGN. Therefore, the control logic stage 804 is configured to generate at least one trigger signal TRG based on the first delayed set of the RQL signal(s) DLY₁ and the alignment signal ALGN. As an example, the digital logic 708 can be aligned/calibrated in a number of ways based on receiving the alignment signal ALGN, such as at power-up of the receiver system 104. As another example, the receiver system 104 can perform periodic calibrations to realign the phases of the first and second clock signals CLK₁ and CLK₂ in response to phase-drift (e.g., detected by the isochronous phase-drift tracking receiver system 200). For example, the digital logic 708 can be calibrated based on the transmitter system 12 being commanded to stop sending data, and to instead begin sending all logic-zeroes. The alignment signal ALGN can then be pulsed, and the transmitter system 102 can be commanded to send a single one data bit (e.g., a training pulse) followed by at least one more zero.

The digital logic 800 also includes a waveform analysis logic stage 806 that receives the second delayed set of the RQL signal(s) DLY₂ and the trigger signal(s) TRG. The waveform analysis logic stage 806 can be configured to latch the logic states of the second delayed set of the RQL signal(s) DLY₂ in response to the trigger signal(s) TRG. The waveform analysis logic stage 806 thus determines which of the phase-aligned RQL signal(s) RQL₀, RQL₉₀, RQL₁₈₀, and RQL₂₇₀ to include in the phase-alignment signal for a single bit time.

The digital logic 800 also includes a selector logic stage 808 that is configured to receive a third delayed set of the RQL signal(s) DLY₃ and the latched logic values of the RQL signal(s) RQL₀, RQL₉₀, RQL₁₈₀, and RQL₂₇₀. The selector logic stage 808 can include a set of selector logic gates that are configured to provide sequential logic operations on the at least one latched RQL signal from the waveform analysis logic stage 806 and the third delayed set of the RQL signal(s) DLY₃ to generate the phase-alignment signal that is aligned to the sampling phase of the second clock signal CLK₂.

Additional details of the operation of the digital logic 800 with respect to the alignment logic stage 802, the control logic stage 804, and the waveform analysis logic stage 806 are described in U.S. Pat. No. 9,876,505 which is incorporated herein by reference in its entirety.

As one example, the selector logic stage 808 can continuously perform logic-AND operations on the third delayed set of the RQL signal(s) DLY₃ with the window from the latched RQL signal(s) RQL₀, RQL₉₀, RQL₁₈₀, and RQL₂₇₀ from the waveform analysis logic stage 806. The selector logic stage 808 can thus perform a logic-OR operation on the outputs of the respective AND-gates to produce a single data output that is aligned with a given one phase of the second clock signal CLK₂. In this example, the logic operations can be implemented to provide phase-drift tracking with a relatively lower resolution, such as for a communication system in which the transmission lines between the transmitter system 102 and the receiver system 104 have approximately equal length.

As another example, the selector logic stage 808 can continuously perform logic-XOR operations on the third delayed set of the RQL signal(s) DLY₃ with the window from the latched RQL signal(s) RQL₀, RQL₉₀, RQL₁₈₀, and RQL₂₇₀ from the waveform analysis logic stage 806. The selector logic stage 808 can thus perform a logic-OR operation on the outputs of the respective AND-gates to produce a single data output that is aligned with a given one phase of the second clock signal CLK₂. In this example, the logic operations can be implemented to provide phase-drift tracking with a relatively higher resolution, such as for a communication system in which the transmission lines between the transmitter system 102 and the receiver system 104 have varying length.

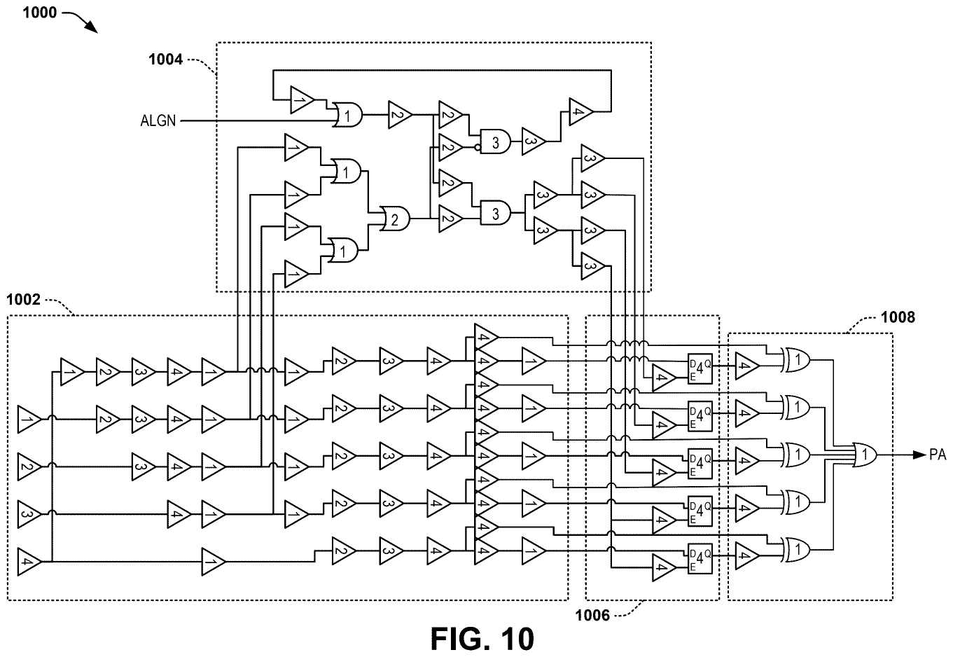

FIGS. 9 and 10 demonstrate separate examples of the digital logic 708, such that each corresponds to the digital logic 800 in the example of FIG. 8. Particularly, FIG. 9 illustrates an example of digital logic 900 that includes an alignment logic stage 902, a control logic stage 904, a waveform analysis logic stage 906, and a selector logic stage 908. FIG. 10 illustrates another example of digital logic 1000 that includes an alignment logic stage 1002, a control logic stage 1004, a waveform analysis logic stage 1006, and a selector logic stage 1008. In the examples of FIGS. 9 and 10, each of the buffers demonstrated correspond to JTLs that are clocked based on a given phase of the second clock signal CLK₂, numbered 1, 2, 3, and 4 (e.g., corresponding to 0°, 90°, 180°, and 270°, respectively). Similarly, logic-OR gates, logic-AND gates, logic-XOR gates, and D-latches are likewise clocked based on the respective phases of the second clock signal CLK₂, numbered 1, 2, 3, and 4.

The digital logics 900 and 1000 are demonstrated in the respective examples of FIGS. 9 and 10 as being fabricated the same, with the exception of the respective selector logic stages 908 and 1008. In the example of FIG. 9, the selector logic stage 908 includes a set of AND-gates to provide AND-operations on the latched RQL signal(s) RQL₀, RQL₉₀, RQL₁₈₀, and RQL₂₇₀ and the set of phase-aligned and delayed RQL signal(s) RQL₀, RQL₉₀, RQL₁₈₀, and RQL₂₇₀ provided from the alignment logic stage 902 to provide a set of AND-outputs. Two sets of two of the AND-outputs are provided to a pair of OR-gates to provide respective logic OR-operations, with the OR-outputs of the pair of OR-gates being provided to another OR-gate that is cascaded from the pair of OR-gates to provide another logic OR-operation. The OR-output of the cascaded OR-gate is provided to an output OR-gate and a last of the AND-outputs that is delayed by a JTL stage buffer to provide a logic OR-operation. The OR-output of the output OR-gate thus corresponds to the phase-alignment signal PA. Accordingly, the phase-alignment signal PA provides a sequence of RQL pulses at each of a defined phase (e.g., 90°) of the second clock signal CLK₂. As an example, the digital logic 900 can be implemented to provide phase-drift tracking with a relatively lower resolution, such as for a communication system in which the transmission lines between the transmitter system 102 and the receiver system 104 have approximately equal length.

In the example of FIG. 10, the selector logic stage 1008 includes a set of XOR-gates to provide logic XOR-operations on the latched RQL signal(s) RQL₀, RQL₉₀, RQL₁₈₀, and RQL₂₇₀ and the set of phase-aligned and delayed RQL signal(s) RQL₀, RQL₉₀, RQL₁₈₀, and RQL₂₇₀ provided from the alignment logic stage 1002 to provide a set of XOR-outputs. The XOR-outputs are all provided an output OR-gate to provide a logic OR-operation. Based on the design considerations of RQL logic circuits, the output OR-gate can correspond to multiple cascaded OR-gates to accommodate more than two (e.g., five) inputs. The OR-output of the output OR-gate thus corresponds to the phase-alignment signal PA. Accordingly, the phase-alignment signal PA provides a sequence of RQL pulses at each of a defined phase (e.g., 0°) of the second clock signal CLK₂. As an example, the digital logic 1000 can be implemented to provide phase-drift tracking with a relatively higher resolution, such as for a communication system in which the transmission lines between the transmitter system 102 and the receiver system 104 have varying length.

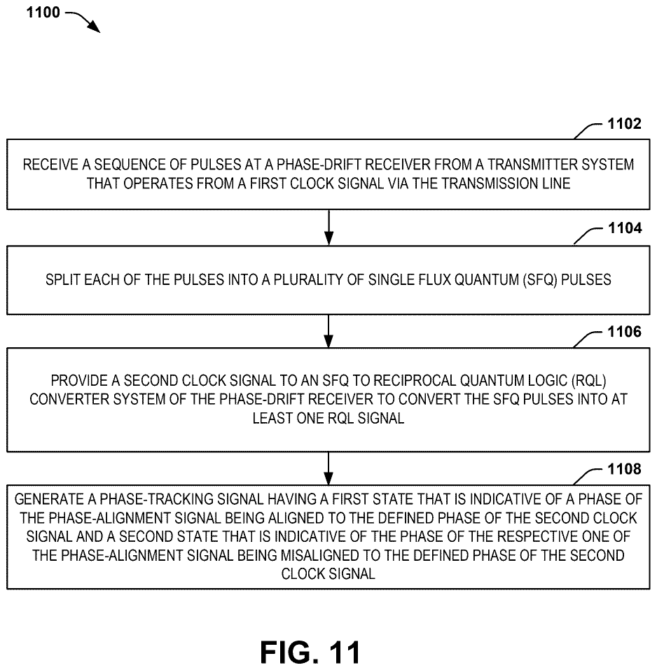

In view of the foregoing structural and functional features described above, a method in accordance with various aspects of the present disclosure will be better appreciated with reference to FIG. 11. While, for purposes of simplicity of explanation, the method of FIG. 11 is shown and described as executing serially, it is to be understood and appreciated that the present disclosure is not limited by the illustrated order, as some aspects could, in accordance with the present disclosure, occur in different orders and/or concurrently with other aspects from that shown and described herein. Moreover, not all illustrated features may be required to implement a method in accordance with an aspect of the present disclosure.

FIG. 11 illustrates a method 1100 for tracking phase-drift of data from a transmission line (e.g., the transmission line 110). At 1102, a sequence of pulses (e.g., the pulses PLS) are received at a phase-drift receiver (e.g., the phase-drift receiver 202) from a transmitter system (e.g., the transmitter system 102) that operates from a first clock signal (e.g., the first clock signal CLK₁) via the transmission line. At 1104, each of the pulses are split into a plurality of SFQ pulses (e.g., the SFQ pulses SFQ₁ and SFQ₂, and the SFQ pulses SFQ₁ and SFQ_{X}). At 1106, a second clock signal (e.g., the second clock signal CLK₂) is provided to an SFQ-RQL converter system (e.g., the SFQ-RQL converters 306) of the phase-drift receiver to convert the SFQ pulses into at least one RQL signal (e.g., the RQL pulses RQL_{P1} through RQL_{PN}). Each of the at least one RQL signal can be associated with a respective one of a plurality of phases of the second clock signal. One of the at least one RQL signal can correspond to a phase-alignment signal (e.g., the phase-alignment signal PA) that is aligned to a defined phase of the second clock signal. At 1108, a phase-tracking signal (e.g., the phase-tracking signal PT) is generated having a first state that is indicative of a phase of the phase-alignment signal being aligned to the defined phase of the second clock signal and a second state that is indicative of the phase of the respective one of the phase-alignment signal being misaligned to the defined phase of the second clock signal.

What have been described above are examples of the disclosure. It is, of course, not possible to describe every conceivable combination of components or method for purposes of describing the disclosure, but one of ordinary skill in the art will recognize that many further combinations and permutations of the disclosure are possible. Accordingly, the disclosure is intended to embrace all such alterations, modifications, and variations that fall within the scope of this application, including the appended claims.

What is claimed is:

1. An isochronous phase-drift tracking receiver system configured to receive a sequence of pulses from a transmitter system that operates from a first clock signal via a transmission line, to initially align the sequence of pulses to a defined phase of a second clock signal, and to generate a phase-tracking signal having a first state that is indicative of a phase of the sequence of pulses being aligned to the defined phase of the second clock signal and a second state that is indicative of the phase of the sequence of pulses being misaligned to the defined phase of the second clock signal.

2. The system of claim 1, comprising a phase-drift receiver configured to receive the sequence of pulses from the transmitter system via the transmission line and to generate a phase-alignment signal corresponding to sequence of reciprocal quantum logic (RQL) pulses indicative of the sequence of pulses being aligned to the defined phase of the second clock signal.

3. The system of claim 2, wherein the phase-alignment signal corresponds to the phase-tracking signal.

4. The system of claim 2, further comprising:
a pulse generator configured to generate a sequence of reference pulses at the defined phase of the second clock signal; and
an XOR gate configured to provide an XOR operation on the phase-alignment signal and the sequence of reference pulses to generate the phase-alignment signal.

5. The system of claim 2, wherein the phase-drift receiver comprises:
an SFQ receiver configured to receive each of the sequence of pulses and to generate an SFQ pulse;
an SFQ splitter stage configured to split the SFQ pulse into a plurality of SFQ pulses;
a plurality of SFQ-RQL converters that are each configured to sample one of the SFQ pulses at a respective phase of the second clock signal to generate at least one RQL signal; and
digital logic configured to generate the phase-alignment signal that is aligned with the second clock signal based on the at least one RQL signal.

6. The system of claim 5, wherein the digital logic comprises:
an alignment logic stage configured to phase-align and delay each of the at least one RQL signal to provide a first at least one phase-aligned and delayed RQL signal and a second at least one phase-aligned and delayed RQL signal;
a waveform analysis logic stage configured to latch the first at least one phase-aligned and delayed RQL signal in response to at least one trigger signal to provide a latched at least one RQL signal; and
a selector logic stage configured to align one of the latched at least one RQL signal to the defined phase of the second clock signal based on the second at least one phase-aligned and delayed RQL signal to provide the phase-alignment signal.

7. The system of claim 6, wherein the transmission line is a first transmission line of a plurality of transmission lines, wherein the transmission lines have an approximately same physical length, wherein the selector logic stage comprises:
a set of AND-gates to provide AND-operations on the latched at least one RQL signal and the second at least one phase-aligned and delayed RQL signal to provide first AND-outputs and a delayed AND-output;
a set of cascaded OR-gates configured to provide OR-operations on the first AND-outputs to provide an OR-output; and
an output OR-gate configured to provide an OR-operation on the OR-output and the delayed AND-output to generate the phase-alignment signal.

8. The system of claim 6, wherein the transmission line is a first transmission line of a plurality of transmission lines, wherein the transmission lines have varying physical length, wherein the selector logic stage comprises:
a set of XOR-gates to provide XOR-operations on the latched at least one RQL signal and the second at least one phase-aligned and delayed RQL signal to provide XOR-outputs; and
an output OR-gate configured to provide an OR-operation on the XOR-outputs to generate the phase-alignment signal, the phase-alignment signal corresponding to the phase-tracking signal.

9. The system of claim 6, further comprising a control logic stage configured to receive an alignment signal and to generate the at least one trigger signal in response to the alignment signal and at least one of the phase-aligned and delayed RQL signals.

10. The system of claim 5, wherein the digital logic is configured to phase-align and delay the at least one RQL signal to generate phase-aligned and delayed RQL signals, and to perform XOR-operations on the phase-aligned and delayed RQL signals to generate the phase-alignment signal, the phase-alignment signal corresponding to the phase-tracking signal.

11. A method for tracking phase-drift of data from a transmission line, the method comprising:
receiving a sequence of pulses at a phase-drift receiver from a transmitter system that operates from a first clock signal via the transmission line;
splitting each of the pulses into a plurality of single flux quantum (SFQ) pulses;
providing a second clock signal to an SFQ to reciprocal quantum logic (RQL) converter system of the phase-drift receiver to convert the SFQ pulses into at least one RQL signal, each of the at least one RQL signal being associated with a respective one of a plurality of phases of the second clock signal, one of the at least one RQL signal corresponding to a phase-alignment signal that is aligned to a defined phase of the second clock signal; and
generating a phase-tracking signal having a first state that is indicative of a phase of the phase-alignment signal being aligned to the defined phase of the second clock signal and a second state that is indicative of the phase of the respective one of the phase-alignment signal being misaligned to the defined phase of the second clock signal.

12. The method of claim 11, further comprising:
generating a sequence of reference pulses at the defined phase of the second clock signal; and
providing an XOR-operation on the phase-alignment signal and the sequence of reference pulses to generate the phase-alignment signal.

13. The method of claim 11, wherein generating the phase-tracking signal comprises:
phase-aligning and delaying each of the at least one RQL signal to provide a first at least one phase-aligned and delayed RQL signal and a second at least one phase-aligned and delayed RQL signal;
latching the first at least one phase-aligned and delayed RQL signal in response to at least one trigger signal to provide a latched at least one RQL signal; and
aligning one of the latched at least one RQL signal to the defined phase of the second clock signal based on the second at least one phase-aligned and delayed RQL signal to provide the phase-alignment signal.

14. The method of claim 13, wherein aligning the respective one of the latched at least one RQL signal comprises:
providing AND-operations on the latched at least one RQL signal and the second at least one phase-aligned and delayed RQL signal to provide first AND-outputs and a delayed AND-output;
providing first OR-operations on the first AND-outputs to provide an OR-output; and
providing a second OR-operation on the OR-output and the delayed AND-output to generate the phase-alignment signal.

15. The method of claim 13, wherein aligning the respective one of the latched at least one RQL signal comprises:
providing XOR-operations on the latched at least one RQL signal and the second at least one phase-aligned and delayed RQL signal to provide XOR-outputs; and
providing an OR-operation on the XOR-outputs to generate the phase-alignment signal, the phase-alignment signal corresponding to the phase-tracking signal.

16. An isochronous phase-drift tracking system comprising:
a transmitter system comprising a phase-drift tracking transmitter configured to generate a sequence of pulses;
a transmission line to transmit the sequence of pulses from the transmitter system; and
a receiver system comprising an isochronous phase-drift tracking receiver system configured to receive the sequence of pulses via the transmission line, to initially align the sequence of pulses to a defined phase of a second clock signal, and to generate a phase-tracking signal having a first state that is indicative of a phase of the sequence of pulses being aligned to the defined phase of the second clock signal and a second state that is indicative of the phase of the sequence of pulses being misaligned to the defined phase of the second clock signal.

17. The system of claim 16, wherein the isochronous phase-drift tracking receiver system comprises a phase-drift receiver configured to receive the sequence of pulses from the transmitter system via the transmission line and to generate a phase-alignment signal corresponding to sequence of reciprocal quantum logic (RQL) pulses indicative of the sequence of pulses being aligned to the defined phase of the second clock signal.

18. The system of claim 17, wherein the phase-drift receiver comprises:
an SFQ receiver configured to receive each of the sequence of pulses and to generate an SFQ pulse;
an SFQ splitter stage configured to split the SFQ pulse into a plurality of SFQ pulses;
a plurality of SFQ-RQL converters that are each configured to sample one of the SFQ pulses at a respective phase of the second clock signal to generate at least one RQL signal; and
digital logic configured to generate the phase-alignment signal that is aligned with the second clock signal based on the at least one RQL signal.

19. The system of claim 18, wherein the transmission line is a first transmission line of a plurality of transmission lines, wherein the transmission lines have varying physical length, wherein the digital logic is configured to phase-align and delay the at least one RQL signal to generate phase-aligned and delayed RQL signals, and to perform XOR-operations on the phase-aligned and delayed RQL signals to generate the phase-alignment signal, the phase-alignment signal corresponding to the phase-tracking signal.

20. The system of claim 18, wherein the transmission line is a first transmission line of a plurality of transmission lines, wherein the transmission lines have an approximately same physical length, wherein the digital logic is configured to phase-align and delay the at least one RQL signal to generate phase-aligned and delayed RQL signals, and to perform AND-operations on the phase-aligned and delayed RQL signals and OR-operations on outputs of the AND-operations to generate the phase-alignment signal.
